(19) United States
(12) Patent Application Publication
(10) Pub. No.: US 2005/0162295 A1
(43) Pub. Date: Jul. 28, 2005

(54) Analog-to-digital converter comprising a sigma-delta modulator

(76) Inventors: Victor Dias, Unterbiberg (DE); Christoph Schwoerer, Vaterstetten (DE)

Correspondence Address: ESCHWEILER & ASSOCIATES, LLC;NATIONAL CITY BANK BUILDING, 629 EUCLID AVE., SUITE 1210, CLEVELAND, OH, 44114, US

(21) Appl. No.: 10/765,784

(22) Filed: Jan. 27, 2004

(51) Int. Cl. H03M 3/00

(52) U.S. Cl. 341/143

(57) ABSTRACT

An analog-to-digital converter is presented, which comprises at least two quantization stages, wherein the final quantization stage comprises a sigma-delta modulator.

### FIELD OF THE INVENTION

The invention relates to analog-to-digital converters. In particular, the invention deals with pipeline analog-to-digital converters and sigma-delta modulators.

### BACKGROUND OF THE INVENTION

An electronic device that performs a conversion from an analog signal to a digital sequence is called an analog-to-digital converter (ADC). Analog-to-digital converters are key blocks of modern medium to wideband wireless transceivers. Examples among others are the analog-to-digital converters required for the standards 802.11.a and HiperLAN-II (with a signal bandwidth of circa 20 MHz), UMTS and all its CDMA precursors and derivatives (with a signal bandwidth of circa 5 MHz) and Bluetooth (with a signal bandwidth of circa 1 MHz).

For the applications of the analog-to-digital converters mentioned above, two architectures have essentially been used in prior art, namely the sigma-delta architecture and the pipeline architecture.

The sigma-delta architecture is mainly used in applications with a signal bandwidth of up to a few MHz, as is the case of Bluetooth and wideband-CDMA.

The pipeline architecture is a member of the so-called Nyquist-rate ADC family. Pipeline analog-to-digital converters are mainly used in WirelessLAN applications, whose signal bandwidths are slightly smaller than 20 MHz.

Reducing the power consumption is one of the main targets when designing the architecture of an analog-to-digital converter as the power consumption directly impacts on the stand-by time and the active time of battery operated hand-held devices, such as mobile phones, PDAs, headsets and notebook computers.

Although state-of-the-art pipeline and sigma-delta analog-to-digital converters can be considered nowadays to be very efficient in terms of power consumption, further improvements towards this direction need to be pursued.

### SUMMARY OF THE INVENTION

It is an object of the present invention, therefore, to provide an analog-to-digital converter with reduced power consumption.

The above formulated object on which the invention is based is achieved by an analog-to-digital converter (ADC) comprising at least two quantization stages, wherein the final quantization stage comprises a sigma-delta modulator (SDM).

In a preferred and advantageous embodiment of the analog-to-digital converter, the processing stages are arranged in a cascade structure.

In other preferred and advantageous embodiments of the analog-to-digital converter, the input terminal of the sigma-delta modulator is connected to the output terminal of the quantization stage (stage N−1) preceding the sigma-delta modulator, wherein a signal (2Q_{N-1}) outputted at said output terminal is a function of the quantization noise processed by said quantization stage (stage N−1).

The invention provides for replacement of the final processing stage of an analog-to-digital converter comprising at least two quantization stages with a sigma-delta modulator. In other words, two or more quantization stages are arranged in a pipeline fashion and the last pipeline stage implementing the final quantization step comprises a sigma-delta modulator. In the following, the quantization stages preceding the sigma-delta modulator in the pipeline are also called front-end stages.

The invention is not restricted to any specific analog-to-digital converter architecture. Rather, the invention applies to any analog-to-digital converter architecture that makes use of two or more processing stages with coarse and fine quantizers. Various names for analog-to-digital converters with at least two quantization stages can be found in the literature. Examples of these names are sub-ranging, two- or multi-step, two- or multi-stage and pipeline analog-to-digital converter.

The invention is furthermore applicable to any sigma-delta modulator, meaning that the sigma-delta modulator that implements the final quantization step can be of any order and can comprise any topology, band, number of quantization bits, etc.

In accordance with an advantageous configuration of the invention, the at least two processing stages are connected in cascade.

According to another advantageous configuration of the invention the input terminal of the sigma-delta modulator is connected to an output terminal of the quantization stage that precedes the sigma-delta modulator in the pipeline. Therefore the sigma-delta modulator receives at its input the quantization noise at the output of the previous quantization stage and implements a noise-shaping of its own quantization noise. Since the front-end stages together have a high gain, when referred to the input, the quantization noise generated by the sigma-delta modulator has a much lower power level compared to that produced by a conventional sigma-delta modulator, as it is divided by a gain 2^{K} of the front-end, where the number K stands for the number of bits extracted of the front-end stages. The low-level quantization noise generated by the sigma-delta modulator is further shaped by the sigma-delta modulator.

The architecture of the analog-to-digital converter according to the invention results in advantages over conventional analog-to-digital converters, where certain of these advantages are listed in the subsequent paragraphs. For understanding these advantages, it has to be taken into consideration that in an ideal pipeline analog-to-digital converter, the quantization noise is due to the final processing stage only because the quantization noise of a quantization stage is always cancelled out by the next stage in the pipeline.

1. An N-bit pipeline analog-to-digital converter constructed according to the invention shows a signal-to-quantization noise ratio that is equivalent to a conventional (N+k)-bit architecture. The number k is a function of the oversampling factor and of the noise-shaping order implemented by the sigma-delta modulator. This will be explained below in more detail.

2. The in-band signal-to-quantization noise ratio of a conventional N-bit analog-to-digital converter can be achieved when using an (N−k)-bit pipeline analog-to-digital converter together with a sigma-delta modulator arranged at the end of the pipeline. Since k pipeline stages can be eliminated by the use of a low-order sigma-delta modulator, an analog-to-digital converter according to the invention requires less power and area than a conventional analog-to-digital converter with the same resolution.

3. Since the sigma-delta modulator will mostly implement a low-order noise shaping of its low-level quantization noise, the invention helps to reduce the complexity of the digital decimator with respect to that required by high-order sigma-delta modulators. Consequently power consumption and implementation area are drastically reduced.

4. The risk of having limit cycles in the sigma-delta modulator is largely reduced by the invention. The reason for this is that on the one hand the input signal of the sigma-delta modulator is pre-processed and randomised by the front-end stages and that on the other hand the weight of the bits delivered by the sigma-delta stage are attenuated by the overall gain of the front-end stages.

5. The quantization noise of the analog-to-digital converter according to the invention as a whole has less spurious tones than the quantization noise of the corresponding pipeline.

### BRIEF DESCRIPTION OF THE DRAWINGS

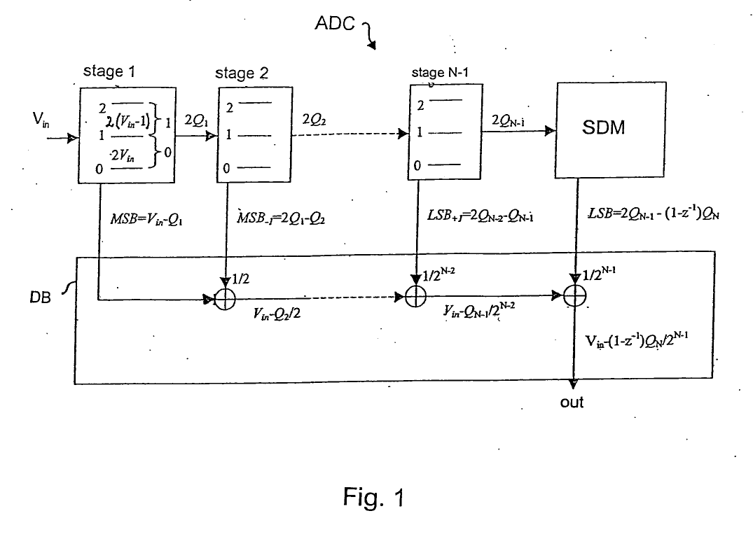

The invention is explained below in an exemplary manner with reference to the drawing, in which FIG. 1 shows the block diagram of an exemplary embodiment of the analog-to-digital converter according to the invention.

### DETAILED DESCRIPTION OF THE INVENTION

An analog-to-digital converter ADC, whose architecture is depicted in FIG. 1, comprises analog processing stages 1 to N−1, a sigma-delta modulator SDM and a digital block DB.

Each of the stages 1 to N−1 is a conventional 1-bit quantizer and gain-stage.

Together with the digital block DB, the stages 1 to N−1 and the sigma-delta modulator SDM are connected in cascade.

In the following the function of the analog-to-digital converter ADC will be explained.

The stage 1 receives an analog input signal Vᵢₙ at its input. For ease of reference, the exemplary analog-to-digital converter ADC illustrated and described herein is assumed to have an input range between 0V and 2V, although other input ranges are possible within the scope of the present invention.

The stage 1 implements a 1-bit quantization of the input signal Vᵢₙ. Afterwards, the stage 1 performs a subtraction of a reference and a multiplication by a factor of two. In more concrete terms this means:

If Vᵢₙ<1V, the stage 1 extracts a “0” for the most significant bit (MSB) and sends it to the digital block DB. Furthermore the stage 1 delivers the signal 2Vᵢₙ to the next stage in the pipeline, namely to the stage 2.

If Vᵢₙ>=1V, the stage 1 extracts a “1” for the MSB and sends it to the digital block DB. The stage 1 also delivers the signal 2 (Vᵢₙ−1) to the stage 2.

This also means that a quantization noise Q₁ amplified by a factor of 2 is passed to the stage 2. Thus, the signal 2Q₁ that is passed to the stage 2 is in the range between 0V and 2V. The bit MSB which is sent to the digital block DB, consists of the input signal Vᵢₙ subtracted by the quantization noise Q₁.

The stage 2 performs the same basic operations as the stage 1. In particular, the stage 2 generates a bit MSB₋₁ given by the term 2Q₁-Q₂ and sends it to the digital block DB. The weight of the bit MSB₋₁ is ½ of the weight of the bit MSB. The stage 2 also calculates the term 2Q₂ from its quantization noise Q₂ and passes this term to the next stage, namely to a subsequent stage (stage 3, not shown).

After the addition of the bits MSB and MSB₋₁ in the digital block DB the quantization noise Q₁ of the stage 1 is cancelled when considering the different weights of the bits MSB and MSB₋₁.

The stages 3 to N−1 repeat the same operations previously performed by the stages 1 and 2. Finally the stage N−1 passes twice its quantization noise QN−1 (e.g., 2Q_{N-1}) to the sigma-delta modulator SDM, which represents the last pipeline stage, and the stage N−1 produces a bit LSB₊₁. The bit LSB₊₁ contains a term that cancels the quantization noise of all previous stages when added up with the bits produced by the previous stages 1 to N−2.

In the present exemplary embodiment of the invention the sigma-delta modulator SDM is a 1^{st} order sigma-delta modulator. The sigma-delta modulator SDM carries out a 1-bit quantization of its input signal 2Q_{N-}1, while simultaneously highpass-shaping its respective quantization error. The bit LSB (least significant bit) outputted by the sigma-delta modulator SDM contains the delayed input signal 2Q_{N-}1 and the quantization noise Q_{N} of the sigma-delta modulator SDM shaped by the term 1−z⁻¹. Adding the bit LSB with the previously produced bits in the digital block DB leads to the cancellation of the quantization noise Q_{N-1}.

Since the quantization noise Q_{N} of the sigma-delta modulator SDM is highpass shaped, filtering and decimation has the potential to bring additional bits of resolution if compared to conventional pipeline stages.

It should be noticed that the sigma-delta modulator SDM outputs two levels, +1 and −1. The reason for this is that the comparator inside the sigma-delta modulator SDM compares if its input signal 2Q_{N-}1 is above or below zero and allocates the outputs +1 and −1 respectively. The quantization noise processed by the sigma-delta modulator SDM is in the range between −1 and +1, thus having a variance larger than that of a corresponding conventional pipeline stage. The effects of this will be discussed in more detail below.

The task of the digital block DB is to synchronise and to weight the output bits of the pipeline stages according to their position in the pipeline. The digital block DB outputs an N-bit word OUT, which is the output word of the analog-to-digital converter ADC.

In the following, the design equations of the analog-to-digital converter ADC shown in FIG. 1 will be derived.

The oversampling factor M of a conventional pipeline analog-to-digital converter with an N-bit quantizer, a sampling rate F_{S}, an input range V_{range} and a signal bandwidth B can be calculated as follows:

$$M = \frac{{F}_{S}}{2 B} \qquad ( 1 )$$

The quantization step Q, the quantization noise power P_{Q} and the power spectral density P_{PSD}, which is assumed to be constant over frequency, of a conventional pipeline analog-to-digital converter are given by the following equations:

$$\begin{matrix}Q = \frac{{V}_{range}}{{2}^{N}} & ( 2 ) \\ {P}_{Q} = \frac{{Q}^{2}}{12} & ( 3 ) \\ {P}_{PSD} = \frac{{P}_{Q}}{{F}_{S}} & ( 4 )\end{matrix}$$

In the full Nyquist band, the maximum achievable signal-to-noise ratio SNRₘₐₓ₋ₛᵢₙᵤₛ assuming a sinusoidal input signal

$$( {P}_{signal} = \frac{{A}^{2}}{2} ) is \\ {SNR}_{max \text{-} sinus} = \frac{{P}_{signal}}{{P}_{Q}} , \qquad ( 5 )$$

which is known to be 6N+1.76 dB.

In a reduced signal bandwidth B, the signal-to-noise ratio SNR_{in-band} is increased to

$${SNR}_{in \text{-} band} = \frac{{P}_{signal}}{2 {\int }_{0}^{B} {P}_{PSD} ( f ) ⅆ f} = \frac{{P}_{signal}}{{P}_{Q}} M , \qquad ( 6 )$$

which corresponds to 6N+10 log(M)+1.76 dB. The processing gain is thus half a bit per octave of the oversampling factor M.

We assume that the input range of the conventional pipeline analog-to-digital converter is [0; 2]. The bit outputted by the first stage is “1” if the input signal is above 1 and “0” if the input signal is below 1. The quantization error is then between 0 and 1 and the signal that is passed to the next stage is between 0 and 2. The second stage does exactly the same as stage 1, namely it extracts one bit, makes a quantization error in the range [0; 1] and passes an amplified quantization error in the range [0; 2] to the third stage. However, when referred to the input of the analog-to-digital converter, the quantization error of the second stage is divided by 2 and thus in the range [0; 0.5]. If extrapolated to N stages, it can be concluded that the quantization noise of the Nth stage is in the range [0; 2/2^{N}] when referred to the input of the analog-to-digital converter. This agrees with the equation (2) for the quantization step Q and also validates the subsequent equations.

If the last pipeline stage of the analog-to-digital converter previously discussed is replaced with a 1^{st} order sigma-delta modulator, the power spectrum of the quantization noise processed by the sigma-delta modulator is shaped by the transfer function |1−z⁻¹|². This transfer function can be rearranged as follows:

$${\vert 1 - {z}^{- 1} \vert}^{2} = {\vert 1 - {ⅇ}^{- \frac{2 π f}{Fs}} \vert}^{2} = {\vert {ⅇ}^{- \frac{π f}{Fs}} ( {ⅇ}^{\frac{π f}{Fs}} - {ⅇ}^{- \frac{π f}{Fs}} ) \vert}^{2} = 4 {sin}^{2} ( \frac{π f}{Fs} ) \qquad ( 7 )$$

However, it has to be taken into consideration that the quantization error processed by the sigma-delta modulator is twice as large as the quantization error processed by an equivalent, conventional pipeline stage. This can be explained by considering the quantization noise outputted by the pipeline stage preceding the sigma-delta modulator. As said above, the quantization noise processed by the stage N−1 is in the range [0; 1] and the stage N−1 passes a signal in the range [0; 2] to the sigma-delta modulator. The sigma-delta modulator first shifts its input signal to the range [−1; 1] because its feedback pulses are 1 and −1. After the sigma-delta modulation, an opposite shift is undertaken. Since the signal at the input of the comparator has a range which is typically up to [−1.5; 1.5] or even slightly larger and the comparator outputs 1 and −1, it is easy to see that the quantization error can now be in the range [−1; 1]. This range is a factor of 2 larger than the range previously derived for the conventional pipeline stage.

The application of equation (6) together with equation (7) leads to the following in-band signal-to-noise ratio SNR_{in-band}:

$${SNR}_{in \text{-} band} = \frac{{P}_{signal}}{{P}_{Q}} M \frac{1}{8 [ 1 - \frac{M}{π} sin ( \frac{π}{M} ) ]} \qquad ( 8 )$$

In equation (8) the following factor can be identified as the processing gain PG:

$$PG = \frac{M}{8 [ 1 - \frac{M}{π} sin ( \frac{π}{M} ) ]} \qquad ( 9 )$$

In the conventional oversampling-only case, the processing gain PG would be simply the oversampling factor M.

The table shown below compares the processing gain PG obtained by an analog-to-digital converter according to the invention with plain oversampling. The results obtained with a 1^{st} order and 2^{nd} order sigma-delta modulator in the last pipeline stage are also listed.

| | Proc. Gain PG | Proc. Gain PG | Proc. Gain PG |
|---|---|---|---|
| Oversampling | (Plain | (1^{st} order | (2^{nd} order |
| Factor M | Oversampling) | Modulator) | Modulator) |
| 4 | 1.0 bit | 1.1 bit | 1.9 bit |
| 8 | 1.5 bit | 2.6 bit | 4.4 bit |
| 16 | 2.0 bit | 4.1 bit | 6.9 bit |
| 32 | 2.5 bit | 5.6 bit | 9.4 bit |

Although the invention has been illustrated and described with respect to one or more implementations, alterations and/or modifications may be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

1. An analog-to-digital converter comprising:
at least two quantization stages, wherein a final quantization stage comprises a sigma-delta modulator.

2. The analog-to-digital converter of claim 1, wherein the at least two quantization stages are arranged in a cascade structure.

3. The analog-to-digital converter of claim 2, wherein an input terminal of the sigma-delta modulator is connected to an output terminal of the quantization stage preceding the sigma-delta modulator, and wherein a signal outputted at the output terminal is a function of a quantization noise of the quantization stage preceding the sigma-delta modulator.

4. The analog-to-digital converter of claim 1, wherein an input terminal of the sigma-delta modulator is connected to an output terminal of the quantization stage preceding the sigma-delta modulator, and wherein a signal outputted at the output terminal is a function of a quantization noise of the quantization stage preceding the sigma-delta modulator.

5. The analog-to-digital converter of claim 1, wherein the sigma-delta modulator is a 1^{st} order sigma-delta modulator.

6. The analog-to-digital converter of claim 1, wherein the sigma-delta modulator carries out a 1-bit quantization of its input signal, and carries out highpass-shaping of a quantization error of the sigma-delta modulator.

7. The analog-to-digital converter of claim 1, wherein the sigma-delta modulator carries out highpass-shaping a quantization error of the sigma-delta modulator.

8. The analog-to-digital converter of claim 1, wherein a least significant bit outputted by the sigma-delta modulator contains a delayed input signal 2Q_{N-}1 and a quantization noise Q_{N} of the sigma-delta modulator shaped by a term 1−z⁻¹, and wherein Q_{N-1} is a quantization noise of the quantization stage preceding the sigma-delta modulator.

9. The analog-to-digital converter of claim 1, wherein the sigma-delta modulator shifts its input signal from a first range to a second range.

10. The analog-to-digital converter of claim 1, wherein the sigma-delta modulator is a 2^{nd} order sigma-delta modulator.

11. An analog-to-digital converter comprising:
a plurality of cascaded quantization stages 1 to N, N being a positive integer greater than 1, each quantization stage receiving an input and providing a single output bit representative of its input, a first stage receiving a converter input and providing a most-significant-bit output bit, and the remaining stages receiving an amplified quantization noise signal from a preceding stage; and
a digital block coupled with the quantization stages and receiving the output bits from the quantization stages;
wherein a last quantization stage N comprises a sigma-delta modulator that provides a least-significant-bit output bit and carries out highpass-shaping of a quantization error of the sigma-delta modulator.

12. The analog-to-digital converter of claim 11, wherein the sigma-delta modulator is a first order sigma-delta modulator.

13. The analog-to-digital converter of claim 11, wherein the sigma-delta modulator is a second order sigma-delta modulator.

14. The analog-to-digital converter of claim 11, wherein the least significant bit outputted by the sigma-delta modulator contains a delayed input signal 2Q_{N-1} and a quantization noise Q_{N} of the sigma-delta modulator shaped by a term 1−z⁻¹, and wherein Q_{N-1} is a quantization noise of the quantization stage preceding the sigma-delta modulator.

15. The analog-to-digital converter of claim 11, wherein the sigma-delta modulator shifts its input signal from a first range to a second range.

16. The analog-to-digital converter of claim 11, wherein an input terminal of the sigma-delta modulator is connected to an output terminal of a quantization stage preceding the sigma-delta modulator, and wherein a signal outputted at the output terminal is a function of a quantization noise of the quantization stage preceding the sigma-delta modulator.

17. An analog-to-digital converter comprising:
a plurality of cascaded quantization stages 1 to N, N being a positive integer greater than 1, each quantization stage receiving an input and providing a single output bit representative of its input, a first stage receiving a converter input and providing a most-significant-bit output bit, and the remaining stages receiving an amplified quantization noise signal from a preceding stage;
wherein a last quantization stage N comprises a sigma-delta modulator that provides a least-significant-bit output bit and carries out highpass-shaping of a quantization error of the sigma-delta modulator.

18. The analog-to-digital converter of claim 17, wherein the sigma-delta modulator is a first order sigma-delta modulator.

19. The analog-to-digital converter of claim 17, wherein the sigma-delta modulator is a second order sigma-delta modulator.

20. The analog-to-digital converter of claim 17, wherein the least significant bit outputted by the sigma-delta modulator contains a delayed input signal 2Q_{N-1} and a quantization noise Q_{N} of the sigma-delta modulator shaped by a term 1−z⁻¹, and wherein Q_{N-1} is a quantization noise of the quantization stage preceding the sigma-delta modulator.

21. The analog-to-digital converter of claim 17, wherein the sigma-delta modulator shifts its input signal from a first range to a second range.
